(19) United States
(12) Patent Application Publication
(10) Pub. No.: US 2012/0190173 A1
(43) Pub. Date: Jul. 26, 2012

(54) METHOD FOR PACKAGING WAFER

(76) Inventors: Jia-Jin Tu, Tainan City (TW); Ying-Huang Lee, Tainan City (TW)

(21) Appl. No.: 13/204,863

(22) Filed: Aug. 8, 2011

(30) Foreign Application Priority Data
Jan. 20, 2011 (CN) 201110022798.6

(51) Int. Cl. H01L 21/78

(52) U.S. Cl. 438/460; 257/E21.599

(57) ABSTRACT

A method for packaging a wafer is provided, which includes: providing a bare wafer; forming a plurality of through silicon vias across through the bare wafer, the through silicon vias being filled with a conducting metal; forming a redistribution layer on the bare wafer, the redistribution layer being connected to each of the through silicon vias; performing a chemical mechanical polishing process to planarize a surface of the bare wafer; performing a wafer forming process to treat the planarized bare wafer; forming a metal layer on the wafer after processed; forming a plurality of connection pads on the metal layer, the connection pads being respectively electrically connected to their corresponding through silicon vias; forming a passivation layer on the metal layer; and forming a plurality of solder balls or metal bumps on a backside surface of the wafer through which the processed wafer is electrically connected to a substrate.

### BACKGROUND OF THE INVENTION

1. Field of the Invention

The present invention relates to a method for packaging a wafer, and more particularly to a method for packaging a wafer in which the through silicon vias (TSV) and the redistribution layer (RDL) are formed on a bare wafer before the semiconductor circuits are formed thereon.

2. The Prior Arts

In a conventional method for packaging a wafer level package, the wafer is packaged after the circuits have been formed thereon. Because the wafer has the circuitry formed thereon, it is difficult to form the through silicon vias due to the obstruction of the circuit. Furthermore, even if the through silicon vias can be formed, the existing circuitry may still be damaged during the electroplating or vacuum deposition process applied for filling the through silicon vias. Because the formation of the circuitry on the wafer is completed, the insulation problem for the through silicon vias may exist. Furthermore, the surface of the wafer may be damaged during forming a redistribution layer. In one conventional method (as shown in FIG. 1), the chips C1 and C2 are stacked on top of each other and electrically coupled to each other, followed by wire bonding the chips C1 and C2 to a circuit board, and molding the chip package with an encapsulant. After molding, the solder balls 4 are formed on the backside of the packaging substrate.

### SUMMARY OF THE INVENTION

The objective of the present invention is to provide a method for packaging a wafer in which the through silicon vias and the redistribution layer are formed on a bare wafer before the semiconductor circuits are formed on the bare wafer so that the circuits subsequently formed on the wafer will not be damaged. In addition, the breakage or the crack on the wafer will not occur during the movement of the wafer. The upper metal layer and the underlying silicon wafer have a plurality of connection members which allow a plurality of chips to be easily stacked together without wire bonding. Therefore, chip scale packaging can be easily achieved.

To achieve the foregoing objective, the present invention provide a method for packaging a wafer, which comprises: providing a bare wafer; forming a plurality of through silicon vias across through the bare wafer, the through silicon vias being filled with a conducting metal; forming a redistribution layer on the bare wafer, the redistribution layer being connected to each of the through silicon vias; performing a chemical mechanical polishing process to planarize a surface of the bare wafer; performing a wafer forming process to treat the planarized bare wafer; forming a metal layer on the wafer after processed; forming a plurality of connection pads on the metal layer, the connection pads being respectively electrically connected to their corresponding through silicon vias; forming a passivation layer on the metal layer; forming a plurality of solder balls or metal bumps on a backside surface of the wafer through which the wafer is electrically connected to a substrate; and cutting the wafer to form a plurality of chips.

According to an embodiment of the present invention, a plurality of through silicon vias across through the bare wafer are firstly formed at the predetermined positions of the bare wafer, and then the through silicon vias are filled with the conducting metal by electroplating or vacuum deposition techniques. Then, a redistribution layer is formed on the bare wafer, and the redistribution layer is connected to each of the through silicon vias. The patterned metal layer is then formed by deposition, and photolithographic etching processes, and the upmost connection pads on the conventional completed wafer are reversely designed so that the connection pads are formed on the first metal layer of the wafer, and the connection pads are respectively electrically connected to their corresponding through silicon vias. Then, a plurality of solder balls or metal bumps 6 are formed on a backside surface of the wafer through which the wafer is electrically connected to a substrate. The process of the present invention can be compatible with any semiconductor process without the limit of wire bonding.

In the present invention, the cost for the substrate, the wire bonding, and molding/encapsulating process can be reduced. Because the second chip is very thin, the connection members are provided on both the upper and lower surfaces of the chip so that the chips can be stacked on top of each other and electrically coupled to each other without involving the complicated wire bonding and alignment processes. Therefore, in the present invention, a high density chip packaging becomes possible without any limitation, and thereby the conventional packaging space limitation can be overcome. Accordingly, Multi-chip packaging (MCP) or system in packaging (SiP) thus can be performed at the wafer level.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other effective embodiments equally.

FIG. 1 is a schematic view showing a conventional chip stacking structure;

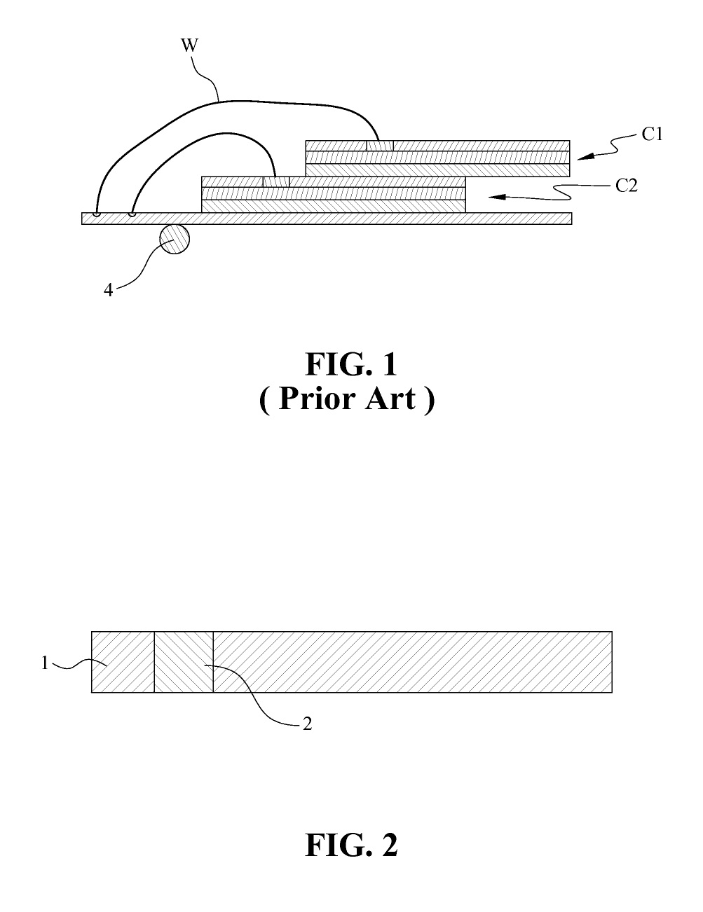

FIGS. 2-5 are schematic views showing the steps of packaging the semiconductor according to an embodiment of this present invention; and

FIG. 6 is a schematic view showing chips stacked on each other using the wafer via packaging method according to the present invention.

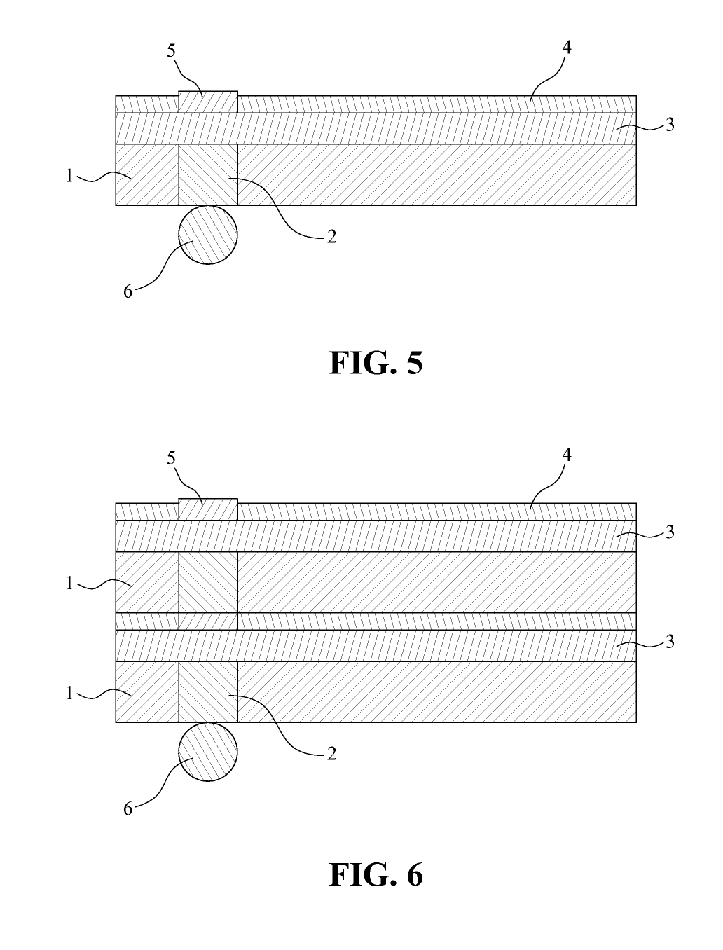

### DETAILED DESCRIPTION OF THE PREFERRED EMBODIMENTS

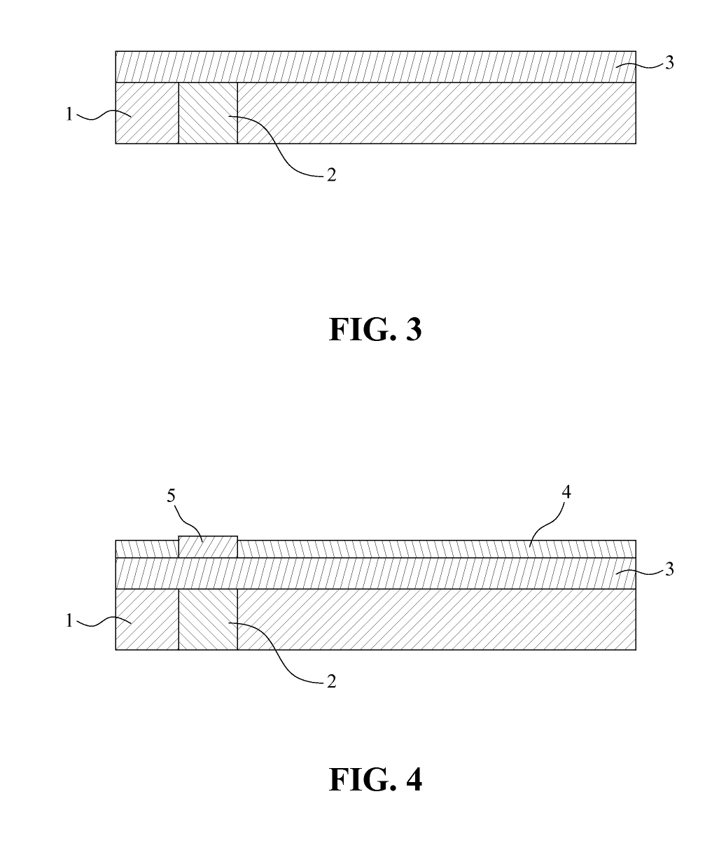

The method for packaging a wafer of the present invention comprises the steps as following: (1) a plurality of through silicon vias across through the bare wafer 1 are formed at the predetermined positions of the bare wafer 1, and the through silicon vias are filled with the conducting metal 2 (as shown in FIG. 2); (2) a redistribution layer is formed on the bare wafer 1, and the redistribution layer is connected to each of the through silicon vias; (3) a chemical mechanical polishing process is performed to planarize a surface of the bare wafer 1; (4) a wafer forming process is performed to treat the planarized bare wafer; (5) a metal layer 3 is formed on the wafer 1 after processed (as shown in FIG. 3); (6) a plurality of connection pads 5 are formed on the metal layer 3, and the connection pads 5 are respectively electrically connected to their corresponding through silicon vias (as shown in FIG. 4); (7) a passivation layer 4 is formed on the metal layer 3 (referring to FIGS. 4); and (8) a plurality of solder balls or metal bumps 6 are formed on a backside surface of the wafer 1 through which the wafer is electrically connected to a substrate (as shown in FIG. 5), and cutting the wafer to form a plurality of chips.

According to an embodiment of the present invention, a plurality of through silicon vias across through the bare wafer are firstly formed at the predetermined positions of the bare wafer, and then the through silicon vias are filled with the conducting metal by electroplating or vacuum deposition techniques. Then, a redistribution layer is formed on the bare wafer, and the redistribution layer is connected to each of the through silicon vias. The patterned metal layer is then formed by deposition, and photolithographic etching processes, and the upmost connection pads on the conventional completed wafer are reversely designed so that the connection pads are formed on the first metal layer of the wafer, and the connection pads are respectively electrically connected to their corresponding through silicon vias. Then, a plurality of solder balls or metal bumps 6 are formed on a backside surface of the wafer through which the wafer is electrically connected to a substrate. The process of the present invention can be compatible with any semiconductor process without the limit of wire bonding.

In the present invention, the cost for the substrate, the wire bonding, and molding/encapsulating process can be reduced. Because the second chip is very thin, the connection members are provided on both the upper and lower surfaces of the chip so that the chips can be stacked on top of each other and electrically coupled to each other without involving the complicated wire bonding and alignment processes. Therefore, in the present invention, a high density chip packaging becomes possible without any limitation, and thereby the conventional packaging space limitation can be overcome. Accordingly, Multi-chip packaging (MCP) or system in packaging (SiP) thus can be performed at the wafer level.

The foregoing description is intended to only provide illustrative ways of implementing the present invention, and should not be construed as limitations to the scope of the present invention. While the foregoing is directed to embodiments of the present invention, other and further embodiments of the invention may thus be devised without departing from the basic scope thereof, and the scope thereof is determined by the claims that follow.

What is claimed is:

1. A method for packaging a wafer, comprising:
providing a bare wafer;
forming a plurality of through silicon vias across through the bare wafer, the through silicon vias being filled with a conducting metal;
forming a redistribution layer on the bare wafer, the redistribution layer being connected to each of the through silicon vias;
performing a chemical mechanical polishing process to planarize a surface of the bare wafer;
performing a wafer forming process to treat the planarized bare wafer;
forming a metal layer on the wafer after processed;
forming a plurality of connection pads on the metal layer, the connection pads being respectively electrically connected to their corresponding through silicon vias;
forming a passivation layer on the metal layer;
forming a plurality of solder balls or metal bumps on a backside surface of the wafer through which the wafer is electrically connected to a substrate; and
cutting the wafer to form a plurality of chips.
